(19) United States
(12) Patent Application Publication
(10) Pub. No.: US 2025/0031305 A1
(43) Pub. Date: Jan. 23, 2025

(54) METHOD AND ELECTRICAL CONTACT ELEMENT

(71) Applicant: Rohde & Schwarz GmbH & Co. KG, München (DE)

(72) Inventors: Mathias NAGEL, Hohenbrunn (DE); Frank EBERHARDT, Memmingen (DE); Michaela SCHLEUDER, München (DE)

(21) Appl. No.: 18/355,506

(22) Filed: Jul. 20, 2023

(51) Int. Cl. H05K 1/03; H05K 1/02; H05K 3/00; H05K 3/32

(52) U.S. Cl. CPC H05K 1/036; H05K 1/0237; H05K 3/0023; H05K 3/328; H05K 2203/0574

(57) ABSTRACT

The present disclosure provides a method for manufacturing an electrical contact element on a circuit structure, the method comprising depositing a separation layer on a carrier substrate, wherein the carrier substrate comprises the circuit structure, forming a structuring layer with a predefined structure on a basic layer that is arranged between the separation layer and the structuring layer, adding an electrical contact element layer by depositing electrically conductive material on the basic layer via the structuring layer according to the predefined structure, and removing the separation layer, and the structuring layer. Further, the present disclosure provides a respective measurement application device.

### TECHNICAL FIELD

The disclosure relates to a method for manufacturing an electrical contact element. Further, the present disclosure relates to a respective electrical contact element.

### BACKGROUND

Although applicable to any type of electrical connection in electrical circuits, the present disclosure will mainly be described in conjunction with electrical connections for high frequency, and microwave applications.

In high-frequency applications, like microwave applications, the sizes, and dimensions of wires, connectors, and traces may be very small.

Accordingly, there is a need for easily connecting wires, contacts, and traces in such applications.

### SUMMARY

The above stated problem is solved by the features of the independent claims. It is understood, that independent claims of a claim category may be formed in analogy to the dependent claims of another claim category.

Accordingly, it is provided:

A method for manufacturing an electrical contact element on a circuit structure, the method comprising depositing a separation layer on a carrier substrate that comprises the circuit structure, forming a structuring layer with a predefined structure on a basic layer, wherein the basic layer is arranged between the separation layer and the structuring layer, adding an electrical contact element layer by depositing electrically conductive material on the basic layer via the structuring layer according to the predefined structure, and removing the separation layer, and the structuring layer.

Further, it is provided:

A measurement application device comprising an electrical contact element manufactured by depositing a separation layer on a carrier substrate, wherein the carrier substrate comprises the circuit structure, forming a structuring layer with a predefined structure on a basic layer, wherein the basic layer is arranged between the separation layer and the structuring layer, adding an electrical contact element layer by depositing electrically conductive material on the basic layer via the structuring layer according to the predefined structure, and removing the separation layer, and the structuring layer. The electrical contact element may comprise at least one mesh structure.

The present disclosure is based on the finding that connecting high frequency circuitry, for example, an inner conductor of a connector, or port to a conductor or trace of an RF circuit, becomes increasingly difficult with diminishing sizes of the elements that need to be connected i.e., with increasing signal frequencies.

In known microwave module assemblies, a connection of an inner conductor of an RF port may e.g., be realized with so called sliding contacts. Such sliding contacts are on one side slid over the inner conductor of the RF port and on the other side soldered onto the conductor of the RF circuit.

However, a sliding-contact-type of connection may not be applied to ports that have inner conductors of very small diameters down to less than 1.0 mm, or 0.8 mm, because of the mechanical instability.

For inner conductors of such small dimensions, gold ribbons may be used that are available in different thicknesses and widths, for example from 6-100 μthickness, and 20-1000 μm width. Such gold ribbons are available e.g., on 100 m rolls, and usually comprise a uniform mesh pattern.

However, the uniform mesh pattern, and the limited selection of widths and thicknesses does not allow for an optimal configuration of each electrical connection.

The present disclosure, therefore, provides the method for manufacturing electrical contact elements, and a respective measurement application device comprising such electrical contact elements.

According to the method, a separation layer is deposited on a carrier substrate that comprises the circuit structure. The separation layer serves for separating the carrier substrate that comprises the circuit structure, and therefor for separating the circuit structure itself, from any other layer that may be arranged temporarily or permanently, as will be described in more detail below, on the carrier substrate, and the circuit structure. With the help of the separation layer, the final electrical contact element may easily be separated at least in specific sections from the carrier substrate for attaching to a respective conductor e.g., of a port, as will be explained in more detail below. The separation layer may comprise a material that on the one hand is sturdy enough to support the manufacturing process, and all the manufacturing steps performed during the process, while on the other hand allowing for a simple removal of the separation layer material after manufacturing the electrical contact element.

In addition, a structuring layer is formed on a basic layer that is arranged between the separation layer and the structuring layer. The structuring layer is formed with a predefined structure. This predefined structure may be chosen according to the required shape of the electrical contact element. This means, that the electrical contact element will be formed based on the predefined structure.

After forming the structuring layer, an electrical contact element layer is added to the basic layer via the structuring layer. The electrical contact element layer is, consequently, added according to the predefined structure that is formed by the structuring layer. The electrical contact element layer may comprise any electrically conductive metal or metal alloy, especially gold. Other electrically conductive materials may comprise, but are not limited to, silver, copper, multilayer arrangements of gold-nickel-gold or other bimetallic systems.

After adding the electrical contact element layer, the separation layer, and the structuring layer are removed, since they are not needed in the final electrical contact element and the circuit structure. Removing the separation layer, and the structuring layer may e.g., be performed by applying an etching process. In case of the usage of a seed layer, as will be described in more detail below, there is no deposition of material of the electrical contact element layer on top of the structuring layer. In case of deposition of material of the electrical contact element layer on the structuring layer the deposited material is automatically removed with the removal of the structuring layer (lift-off).

The final electrical contact element i.e., also the electrical contact element layer, may have a thickness that is larger than 1 um, 5 um, 10 um, 15 um, 20 um or larger than 25 um. The thickness may also be smaller than 30 um, 23 um, 17 um, 13 um or smaller than 8 um. In a specific embodiment, the thickness of the electrical contact element may be between 2 μm and 3 μm. In another embodiment, the thickness may be 10 μm.

The electrical contact element may in embodiments have a rectangular shape, wherein the length of the rectangle may be smaller than 5 mm, 3 mm, 2 mm, 1 mm or smaller than 0.5 mm. In embodiments, the width of the rectangle is smaller than its length.

Since the electrical contact element layer is formed on the carrier substrate with the electrical circuit structure, there is no need to mount the electrical contact element in the circuit structure. Instead, the electrical contact element may automatically be attached to e.g., a conductor of the respective circuit structure.

With the electrical contact element being attached to the respective conductor, the inner conductor of e.g., a respective port, may be placed over the conductor, and the electrical contact element may be folded around the inner conductor of the port. Finally, the electrical contact element may be welded or bonded to the inner conductor e.g., at the top of the inner conductor, where both ends of the folded electrical contact element may overlap, the electrical contact element, therefore, forming a closed loop. The inner conductor of the port is now electrical indirectly connected to the conductor of the RF circuit via this closed loop and therefore the connection is mechanical flexible, to accommodate for e.g., temperature-induced size variations.

The present disclosure provides ready-to-use, individual tailored in-circuit or inter-circuit connections that comprise the predefined structure. These electrical contact elements may electrically interconnect different elements of a circuit, or different circuits that may be provided in the circuit structure, or that may be used to interconnect different circuit structures on the same, or on different carrier substrates, as will be described below in more detail. The predefined structure may be tailored to fragile RF ports with inner conductors of diameters as tiny as 1.0 mm, or 0.8 mm, or even less. In addition, wires, or conductors of different length may be accommodated. The shape of the electrical contact element can be defined in virtually any form. This leads to different properties regarding e.g., stiffness, stress relief, RF characteristics, that may be individually adapted to the respective application.

Other applications of the present disclosure comprise, but are not limited to substitution of virtually any bonded or welded wire assembly, like inter-circuit connections, intra-circuit connections, connection over cut-out/via, and connections on demand.

Further, versatile, well-defined geometries can be manufactured within one process targeting the needs of a “high-mix low-volume” production, since multiple electrical contact elements may be formed in a single process on the carrier substrate as required. Further, the present disclosure allows for a very precise placement of the electrical contact element over the circuit structure e.g., the trace or conductor over which it is produced. Manual cutting, manual placement and one assembly step is skipped (welding on the circuit) as the electrical contact element is already formed onto, and attached to the conductor.

Depending on the electrically conducting material that is used for manufacturing the electrical contact elements, they may be further processed easily by bonding, welding, gluing, or any other adequate connecting technology.

In contrast to traditional bonding or bond wires, the electrical contact element is planarly fixed to the circuit structure, instead of orthogonally like bond wires. This planar fixation may also be advantageous in RF applications.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to the method can be combined in all variations with each other and the disclosure of the description is not limited to the claim dependencies as specified in the claim set. Further, the features of the other independent claims may be combined with any of the features of the dependent claims relating to the method in all variations, wherein respective apparatus elements may perform the respective method steps.

In an embodiment, which can be combined with all other embodiments of the method mentioned above or below, the carrier substrate may comprise, but is not limited to, e.g., a glass wafer, a ceramic wafer, a PCB material, and silicon. Generally, any material may be used as the carrier substrate that offers a respective mechanical stability and temperature resistance, as needed for the further method steps of the method according to the present disclosure, and that is capable of supporting the circuit structure.

In a further embodiment, which can be combined with all other embodiments of the method mentioned above or below, the separation layer may comprise a photoresist material. Possible materials comprise, but are not limited to, positive or negative tone photoresist, spin-on-glass, BCB, which is a specific photoresist, hard wax, other polymers, deposited ceramic material, metal oxidized after deposition e.g., nickel, or chromium. Specific photoresist materials may comprise, but are not limited to, “Fujifilm HPR506” or “SU-8”.

By using a photoresist material for the separation layer, the separation layer may be easily removed when it is not needed anymore in the process of manufacturing the electrical contact element.

The photoresist material used for the separation layer may be the same photoresist material as used for the photoresist layer of the structuring layer, as will be described below in more detail.

In an embodiment, which can be combined with all other embodiments of the method mentioned above or below, forming the separation layer may comprise depositing a first photoresist layer on the basic layer, exposing the first photoresist layer to a light source, and developing the first photoresist layer.

A photoresist layer is a layer of a material that is photosensitive or light-sensitive, such that the photoresist layer may be used to shape the predefined structure. The first photoresist layer may be structured to cover parts of the carrier substrate and the circuit structure that should not unite with the electrical contact element layer. The separation layer will, consequently, as the name implies, separate the carrier substrate from any other layer that may later be provided on top of the separation layer, at least in specific regions or sections. Of course, holes or openings may be provided in the separation layer that allow e.g., the electrical contact element layer to adhere to specific sections e.g., traces or conductors of the circuit structure.

In order to create the first photoresist layer, this layer may be exposed to a light source. A respective mask for exposing only the required regions of the first photoresist layer to the light of the light source may be applied on top of the first photoresist layer.

After exposing the first photoresist layer to the light source, a developer may be added to develop the first photoresist layer. Developing in this regard refers to dissolving the not-required sections of the first photoresist layer by applying the developer.

In an embodiment, which can be combined with all other embodiments of the method mentioned above or below, forming the separation layer may further comprise hardening the separation layer.

Below further explanations will be provided with regard to photoresist layers. Any of these explanations apply mutatis mutandis to the first photoresist layer, as well as to any other photoresist layer disclosed herein.

In an embodiment, which can be combined with all other embodiments of the method mentioned above or below, the separation layer may comprise a thickness between 2 μm, and 50 μm (micrometer).

In embodiments, the separation layer may have a thickness larger than 2 μm, 4 μm, 10 μm, 20 μm, 30 μm or larger than 40 μm. In further embodiments, the thickness may be smaller than 50 μm, 35 μm, 25 μm, 15 μm or smaller than 8 μm.

In an embodiment, the thickness of the separation layer may be between 5 μm and 7 μm, or (within the possible machining tolerances) exactly 6 μm.

In another embodiment, which can be combined with all other embodiments of the method mentioned above or below, the basic layer may comprise a seed layer provided on the separation layer.

The seed layer may be used without the carrier substrate, and the separation layer. The seed layer may in embodiments, however, also be combined with at least one of the carrier substrate i.e., on the circuit structure, and the separation layer.

When combined with the carrier substrate, the seed layer may be provided on the carrier substrate. When combined with the separation layer, the seed layer may be provided on the separation layer, wherein the carrier substrate may be provided below the separation layer.

The seed layer may be provided as a kind of adhesive for the electrically conductive material. The electrically conductive material of the electrical contact element layer may in embodiments be deposited directly on top of the seed layer. The material of the seed layer, therefore, may be chosen according to the electrically conductive material such that the electrically conductive material adheres to the seed layer as required. Possible materials for the seed layer may comprise but are not limited to, gold, and other conductive metals, especially with palladium doping.

In a further embodiment, which can be combined with all other embodiments of the method mentioned above or below, the seed layer may be provided by at least one of DC magnetron sputtering, and a thermal evaporation process. In embodiments, the seed layer may be formed of gold.

It is understood, that any process adequate for providing the seed layer may be used. The process may, of course, be chosen based on the material that is used for the seed layer.

If gold or any of the other materials mentioned above is used as the seed layer, a DC magnetron sputtering process, or a thermal evaporation process may be used to create the seed layer. Of course, the electrical contact element layer may also be deposited by a DC magnetron sputtering process, or a thermal evaporation process.

In another embodiment, which can be combined with all other embodiments of the method mentioned above or below, the seed layer may be formed with a thickness between 5 nm and 300 nm (nanometers).

The thickness of the seed layer may be larger than 40 nm, 80 nm, 100 nm, 150 nm, 200 nm, or larger than 250 nm. Further, in embodiments, the thickness may be smaller than 300 nm, 170 nm, 130 nm, 110 nm or smaller than 70 nm.

In an embodiment, the thickness of the seed layer may be between 90 nm and 110 nm, or (within the possible machining tolerances) exactly 100 nm.

In embodiments, the thickness of the carrier substrate is larger than the thickness of any one of the seed layer, the separation layer, and the structuring layer.

In further embodiments, the thickness of the electrical contact element layer is larger than the thickness of the seed layer. In embodiments, the electrical contact element layer may have a thickness of 2 μm-50 μm, especially between 6 μm-10 μm.

In a further embodiment, which can be combined with all other embodiments of the method mentioned above or below, the seed layer may be formed of the same material as the electrical contact element layer.

By forming the seed layer of the same material as the electrical contact element layer, a good adhesion of the material of the electrical contact element layer on the seed layer is provided.

In another embodiment, which can be combined with all other embodiments of the method mentioned above or below, the seed layer may be removed at least in part with the separation layer, and the structuring layer.

The seed layer may in embodiments not comprise the predefined structure, but may be a planar or full-surface-planar layer. If the predefined structure is specifically chosen for an application to provide advantageous properties, the seed layer may be detrimental for the function of the electrical contact element, if required.

Therefore, the seed layer may be actively removed. For removing the seed layer, for example, an etching process may be applied.

The seed layer may have a thickness that is smaller than the thickness of the electrical contact element layer. In such embodiments, the etching time may be chosen long enough to remove the seed layer, but short enough not to remove the electrical contact element layer.

In other embodiments, other methods for removing the seed layer may be applied e.g., a mechanical grinding or sanding process, or a laser cutting process.

In a further embodiment, which can be combined with all other embodiments of the method mentioned above or below, forming the structuring layer may comprise depositing a second photoresist layer on the basic layer, exposing specific regions of the second photoresist layer to a light source, the specific regions being defined by the predefined structure, and developing the second photoresist layer.

A photoresist layer is a layer of a material that is photosensitive or light-sensitive, such that the photoresist layer may be used to shape the predefined structure with the photoresist layer. In order to shape the structuring layer, the second photoresist layer i.e., specific regions of the second photoresist layer as defined by the predefined structure, are exposed to a light source. A respective mask for exposing only the required regions of the second photoresist layer to the light of the light source may be applied on top of the second photoresist layer.

After exposing the second photoresist layer to the light source, a developer may be added to develop the second photoresist layer. Developing in this regard refers to dissolving the not-required sections of the second photoresist layer by applying the developer.

Applying the developer results in removing of the unwanted sections of the photoresist, wherein the removed parts define the predefined structure of the electrical contact element.

The second photoresist layer may be formed of positive or negative photoresist material.

With a positive photoresist material, that sections of the second photoresist layer that are exposed to light become soluble to a photoresist developer. The unexposed sections of the second photoresist layer remain insoluble to the photoresist developer, and, consequently, are not removed.

With a negative photoresist material, that sections of the second photoresist layer that are exposed to light become insoluble to a photoresist developer. The non-exposed sections of the second photoresist layer remain soluble to the photoresist developer, and, consequently, are removed.

In another embodiment, which can be combined with all other embodiments of the method mentioned above or below, the method may further comprise hardening the structuring layer.

Hardening the structuring layer may comprise e.g., baking or hardbaking the structuring layer i.e., the second photoresist layer, with the basic layer. In embodiments with the carrier substrate, the carrier substrate may be baked with the basic layer, and the second structuring layer. Hardbaking may, for example, comprise baking the structuring layer at 100° C. for about two hours. Generally, the details of the hardbaking may be adapted to the specific photoresist material, and may range from a temperature of 50° C. to a temperature of 150° C., with a duration between 30 minutes and 3 hours.

The explanations provided for the second photoresist layer also apply mutatis mutandis to the first photoresist layer.

In a further embodiment, which can be combined with all other embodiments of the method mentioned above or below, depositing electrically conductive material on the basic layer may comprise at least one of DC magnetron sputtering, and a thermal evaporation.

Since the electrically conductive material may be the same material that is used for the seed layer, the explanations provided herein for the seed layer mutatis mutandis also apply to the electrical contact element layer.

In a further embodiment, which can be combined with all other embodiments of the method mentioned above or below, the predefined structure may comprise a mesh structure in at least a section of the structuring layer.

The mesh structure may be formed e.g., by applying a respective mask when exposing specific regions of the photoresist layer to a light source.

The mesh structure may be provided, especially, in the sections of the structuring layer that represent that sections of the electrical contact element that are later bent to fit around a conductor.

In another embodiment, which can be combined with all other embodiments of the method mentioned above or below, the distance between two holes in the mesh structure may be between 5 μm and 15 μm, and the size of the holes in the mesh structure may be smaller than 40 μm.

The distance between two holes refers to the distance between the outer circumferences of the holes, and may also be denominated as web width or land width. It is understood that the holes may be square shaped. In such embodiments, the distance will be equal along the sides of the holes. In other embodiments, the holes may be shaped as circles. In such embodiments, the term “distance” may refer to the shortest distance between the edges of two holes.

The term “size” of the holes may, in the case of square-shaped holes, refer to the length of each side of the square. In case of rectangularly shaped holes, adjacent sides may have different lengths, each below 40 μm. In case of round or circular holes, the size may refer to the diameter of the holes.

In an embodiment, the distance is 10 μm, and the size of the holes is 30 μm or 29 μm.

In a further embodiment, which can be combined with all other embodiments of the method mentioned above or below, the predefined structure may comprise at least one welding, soldering, or bonding section, wherein the welding section is provided on opposing outer edges of the electrical contact element. It is understood, that a single welding section is also possible. In the present disclosure, the terms welding, soldering, and bonding may be interchanged, where appropriate. This means, that when welding is explicitly stated, soldering or bonding are also possible. Respective welding sections may, therefore, be soldering or bonding sections.

When two welding sections are provided, the two welding sections may be provided on opposing outer edges of the electrical contact element, such that when the electrical contact element is wound around a conductor, the welding sections overlap. The overlapping welding sections may then be spot welder or laser welded together to fix the conductor.

In another embodiment, which can be combined with all other embodiments of the method mentioned above or below, the predefined structure may comprise at least one fixation section. When the electrical contact element layer serves for fixing to an inner conductor of a port or wire, the at least one fixation section may be provided in the center area of the electrical contact element, and two mesh structures may be provided on each one of two opposing sides of the fixation section. If the electrical contact element layer serves for fixing a part of the circuit structure to another part of the circuit structure, the fixation section may be provided on a side or edge of the electrical contact element. In such embodiments, two fixation sections may be provided on two opposing sides or edges of the electrical contact element. In such embodiments, a mesh structure may be provided between the two fixation sections.

The electrical contact element, similarly to the welding sections, serves for fixing the electrical contact element. Instead of fixing the electrical contact element to a conductor of a port. the fixation section serves for fixing the electrical contact element to a trace or conductor of the circuit structure on the carrier substrate. As explained above, the separation layer may comprise holes over specific sections of the carrier substrate and the circuit structure. Such holes may especially be provided over a spot of a trace that need to be electrically contacted.

The predefined structure may comprise the fixation section overlayed over such a spot of the circuit structure. The electrical contact element layer will, therefore, be arranged to comprise the electrically conductive material over the respective spot, and the electrically conductive material will adhere to, and be in electrical contact with the trace, or any other respective element of, or on the carrier substrate, or the circuit structure.

The term “center area” refers to an area between the outer edges of the electrical contact element, and especially to an area in the center of the electrical contact element regarding its axis of greatest longitudinal extension.

In a further embodiment, which can be combined with all other embodiments of the method mentioned above or below, the method may further comprise repeating the steps of forming a structuring layer, and adding an electrical contact element layer for creating a 2.5-dimensional electrical contact element.

Providing a 2.5-dimensional geometry or 2.5-dimensional electrical contact element, refers to creating a three-dimensional structure by applying multiple two-dimensional layers on top of each other.

In another embodiment, which can be combined with all other embodiments of the method mentioned above or below, the method may further comprise repeating the steps of forming a structuring layer, and adding an electrical contact element layer for creating a bimetallic electrical contact element.

The second or further electrical contact element layer may be provided directly on top of the first electrical contact element layer, but may comprise a different electrically conductive material, especially a material with a different thermal expansion coefficient, especially a smaller thermal expansion coefficient, than the material of the first electrical contact element layer.

Stacking these two electrical contact element layers will, therefore, result in a bi-metallic structure, that will e.g., bend upwards when heated.

Although not explicitly claimed, the present disclosure also provides the carrier substrate with the circuit structure and the electrical contact element as separate unit or device.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a flow diagram of an embodiment of a method according to the present disclosure;

FIG. 2 shows a flow diagram of another embodiment of a method according to the present disclosure;

FIG. 3 shows a flow diagram of a further embodiment of a method according to the present disclosure;

FIG. 4 shows a flow diagram of another embodiment of a method according to the present disclosure;

FIG. 5 shows a flow diagram of another embodiment of a method according to the present disclosure;

FIG. 6 shows a block diagram of an embodiment of an electrical contact element according to the present disclosure;

FIG. 7 shows a block diagram of another embodiment of an electrical contact element according to the present disclosure;

FIG. 8 shows a block diagram of another embodiment of an electrical contact element according to the present disclosure;

FIG. 9 shows a block diagram of embodiments of electrical contact elements according to the present disclosure;

FIG. 10 shows a block diagram of another embodiment of an electrical contact element according to the present disclosure;

FIG. 11 shows a block diagram of another embodiment of an electrical contact element according to the present disclosure;

FIG. 12 shows a block diagram of another embodiment of an electrical contact element according to the present disclosure;

FIG. 13 shows a block diagram of another embodiment of an electrical contact element according to the present disclosure;

FIG. 14 shows a block diagram of an oscilloscope for use with an embodiment of an electrical contact element according to the present disclosure; and

FIG. 15 shows a block diagram of another oscilloscope for use with an embodiment of an electrical contact element according to the present disclosure.

In the figures like reference signs denote like elements unless stated otherwise.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

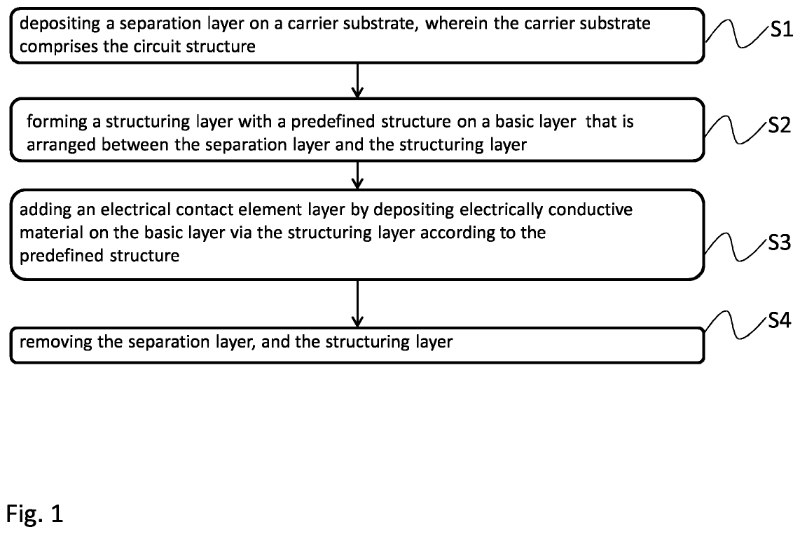

FIG. 1 shows a flow diagram of a method for manufacturing an electrical contact element.

The method comprises depositing S1 a separation layer on a carrier substrate, wherein the carrier substrate comprises the circuit structure, forming S2 a structuring layer with a predefined structure on a basic layer that is arranged between the separation layer and the structuring layer, adding S3 an electrical contact element layer by depositing electrically conductive material on the basic layer via the structuring layer according to the predefined structure, and removing S4 the separation layer, and the structuring layer.

The separation layer is formed on the carrier substrate that carries the circuit structure. Such a carrier substrate further provides mechanical stability during the manufacturing process. The basic layer may serve as intermediate layer between the separation layer, and the structuring layer, as will be described in more detail.

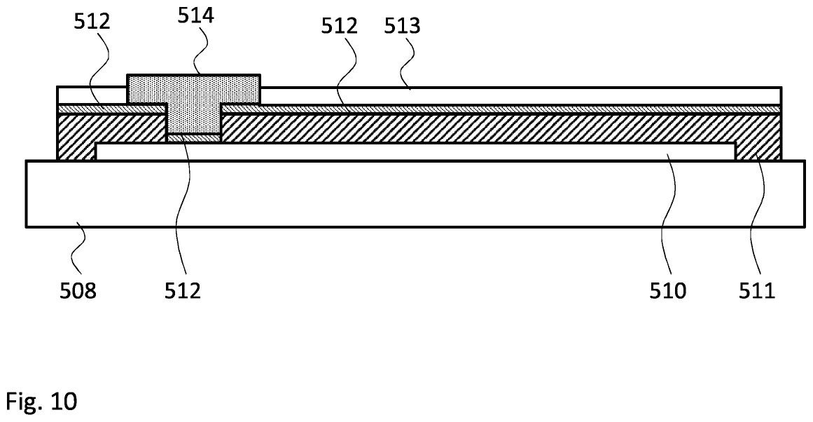

The separation layer may be provided over the circuit structure, and may comprise at least one hole over at least a section of the circuit structure, as will be explained in more detail with regard to FIG. 10.

In embodiments, forming S2 may comprise forming the predefined structure as a mesh structure in at least a section of the structuring layer. The distance between two holes in the mesh structure may in such an embodiment be between 5 μm and 15 μm. In embodiments, the size of the holes in the mesh structure may be smaller than 40 μm.

When forming S2, the structuring layer may be formed such that the predefined structure comprises two welding sections. These welding sections may be provided on opposing outer edges of the electrical contact element.

In other embodiments, when forming S2, the structuring layer may be formed such that the predefined structure comprises at least one fixation section. The fixation section may be provided in the center area of the electrical contact element for attaching the electrical contact element to a conductor or trace of the circuit structure provided on the carrier substrate.

In embodiments, multiple electrical contact element layers may be formed. For example, the steps of forming a structuring layer, and adding an electrical contact element layer may be repeated for creating a 2.5-dimensional electrical contact element.

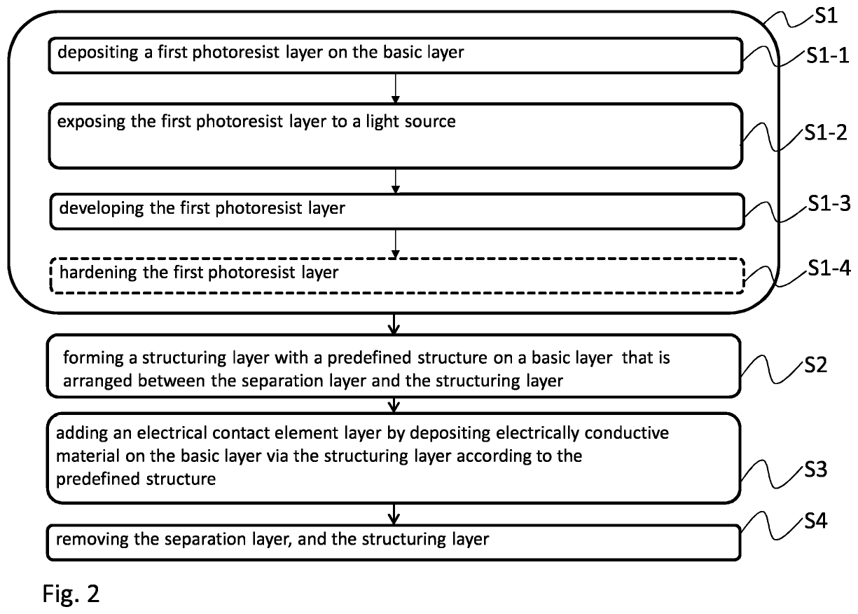

FIG. 2 shows a flow diagram of another method for manufacturing an electrical contact element. The method of FIG. 2 is based on the method of FIG. 1. Therefore, the method of FIG. 2 comprises depositing S1 a separation layer on a carrier substrate, wherein the carrier substrate comprises the circuit structure, forming S2 a structuring layer with a predefined structure on a basic layer that is arranged between the separation layer and the structuring layer, adding S3 an electrical contact element layer by depositing electrically conductive material on the basic layer via the structuring layer according to the predefined structure, and removing S4 the separation layer, and the structuring layer.

In the method of FIG. 2 depositioning S1 the separation layer further comprises depositing S1-1 a first photoresist layer on the basic layer, exposing S1-2 the first photoresist layer to a light source, and developing S1-3 the first photoresist layer. The optional step of hardening S1-4 the separation layer may also be performed.

In embodiments, the separation layer may comprise a photoresist that may later easily be removed or dissolved.

In embodiments, the separation layer may comprise a thickness between 2 μm, and 50 μm.

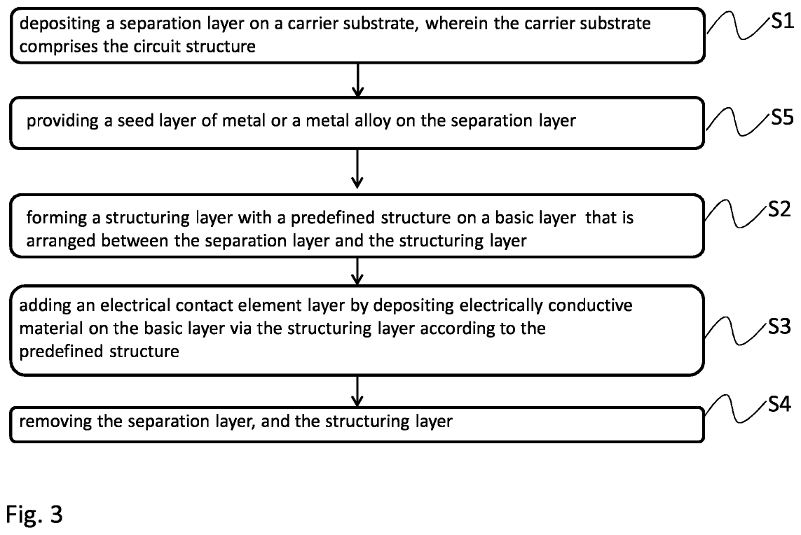

FIG. 3 shows a flow diagram of another method for manufacturing an electrical contact element. The method of FIG. 3 is based on the method of FIG. 1. Therefore, the method of FIG. 3 comprises depositing S1 a separation layer on a carrier substrate, wherein the carrier substrate comprises the circuit structure, forming S2 a structuring layer with a predefined structure on a basic layer that is arranged between the separation layer and the structuring layer, adding S3 an electrical contact element layer by depositing electrically conductive material on the basic layer via the structuring layer according to the predefined structure, and removing S4 the separation layer, and the structuring layer.

The method of FIG. 3 further comprises providing S5 a seed layer on top of the separation layer as part of the basic layer. The seed layer serves for later allowing the material of the electrical contact element layer to easily stick to the seed layer according to the predefined structure.

The seed layer may be formed of the same material as the electrical contact element layer will be formed, especially of gold, and especially with a thickness between 40 nm and 300 nm. Such a seed layer may be provided by at least one of DC magnetron sputtering, and a thermal evaporation process.

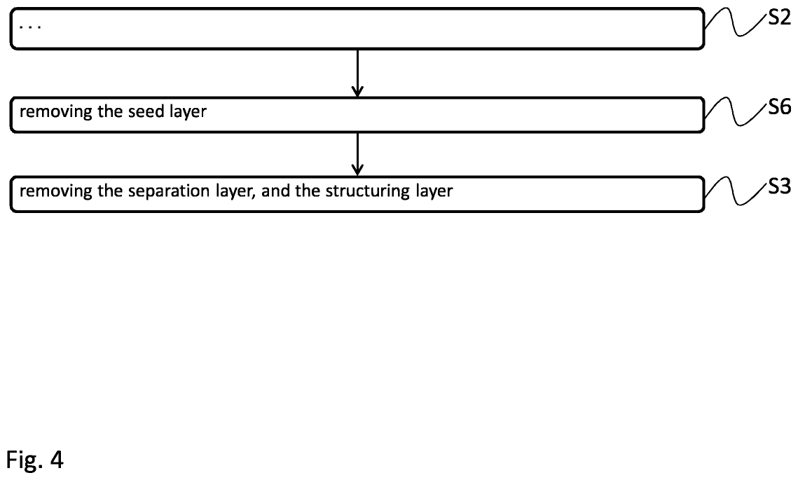

FIG. 4 shows a flow diagram of another method for manufacturing an electrical contact element. The method of FIG. 4 is based on the method of FIG. 1. Therefore, the method of FIG. 4 comprises depositing S1 a separation layer on a carrier substrate, wherein the carrier substrate comprises the circuit structure, forming S2 a structuring layer with a predefined structure on a basic layer that is arranged between the separation layer and the structuring layer, adding S3 an electrical contact element layer by depositing electrically conductive material on the basic layer via the structuring layer according to the predefined structure, and removing S3 the separation layer, and the structuring layer. In FIG. 4, the step S1 is not shown, and the step S2 is only hinted at.

The method of FIG. 4 may be used in embodiments of the method that comprise providing a seed layer, and further comprises after the step S2 removing S6 the seed layer at least in part.

Removing S6 may e.g., comprise edging the seed layer from the electrical contact element layer.

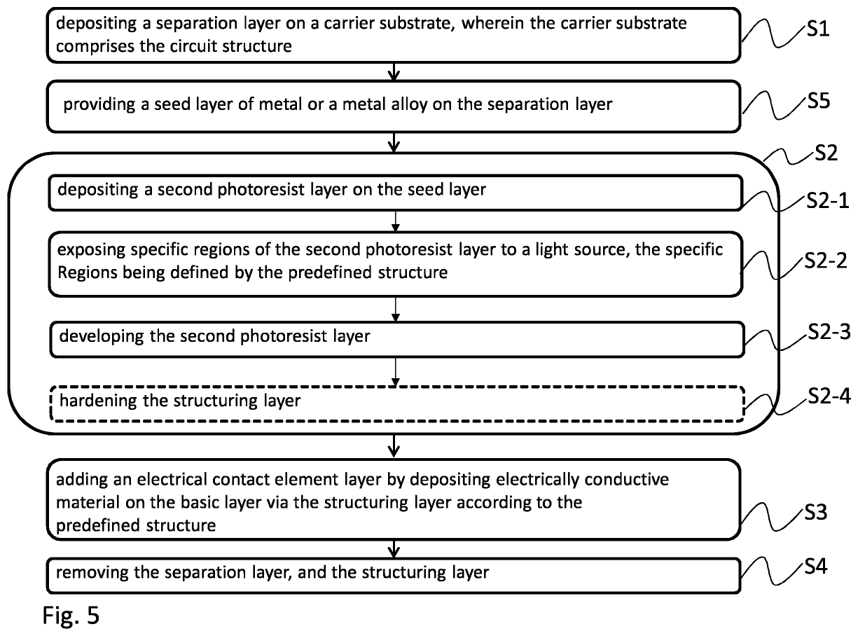

FIG. 5 shows a flow diagram of another method for manufacturing an electrical contact element. The method of FIG. 5 is based on the method of FIG. 1. Therefore, the method of FIG. 5 comprises depositing S1 a separation layer on a carrier substrate, wherein the carrier substrate comprises the circuit structure, forming S2 a structuring layer with a predefined structure on a basic layer that is arranged between the separation layer and the structuring layer, adding S3 an electrical contact element layer by depositing electrically conductive material on the basic layer via the structuring layer according to the predefined structure, and removing S4 the structuring layer.

The method of FIG. 5 further comprises, in the step of forming S2 a structuring layer, the steps of depositing S2-1 a photoresist layer on the basic layer, exposing S2-2 specific regions of the photoresist layer to a light source, the specific regions being defined by the predefined structure, and developing S2-3 the photoresist layer.

The method of FIG. 5 further comprises in the step of forming S2 a structuring layer the optional step S2-4 of hardening the structuring layer if required.

With the additional steps shown in FIG. 5, the predefined structure may easily be created with or in the structuring layer.

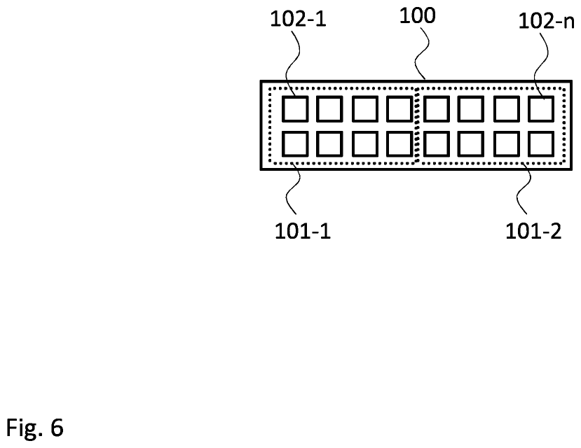

FIG. 6 shows a block diagram of an electrical contact element 100. The electrical contact element 100 comprises two mesh structures 101-1, 101-2. The mesh structures 101-1, 101-2 each comprise two rows each with four holes 102-1-102-n. The mesh structures 101-1, 101-2 are provided left and right of the center of the electrical contact element 100.

The electrical contact element 100 comprises a rectangular shape, wherein the width of the rectangular shape is larger than the height of the rectangular shape.

It is understood, that the electrical contact element 100 may be provide with any other adequate shape by providing a respective predefined structure in the structuring layer.

Further, the number of holes 102-1-102-n may be chosen as adequate and is not limited to the shown number. In general, the size and spacing of the holes 102-1-102-n may e.g., be chosen to such that the sides of the square holes 102-1-102-n is less than 40 μm. The spacing between the holes 102-1-102-n may e.g., be chosen such that the material between two adjacent holes has a width of 5 μm to 15 μm.

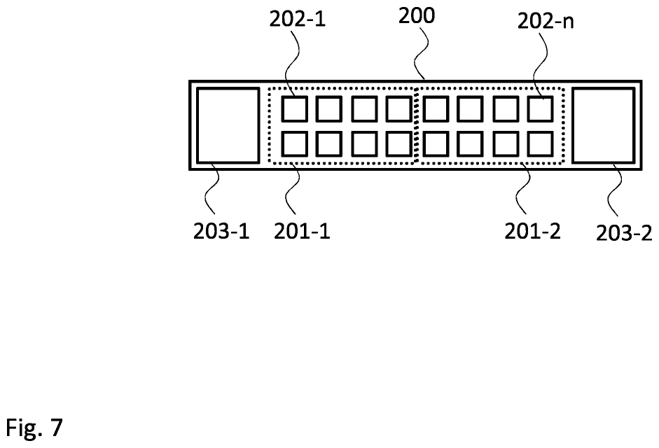

FIG. 7 shows a block diagram of another electrical contact element 200. The electrical contact element 200 is based on the electrical contact element 100. Therefore, the electrical contact element 200 comprises two mesh structures 201-1, 201-2. The mesh structures 201-1, 201-2 each comprise two rows each with four holes 202-1-202-n. The mesh structures 201-1, 201-2 are provided left and right of the center of the electrical contact element 200. The explanations provided regarding the electrical contact element 100 apply mutatis mutandis to the electrical contact element 200.

The electrical contact element 200 is also shaped rectangularly, wherein the mesh structures 201-1, 201-2 are provided in the center of the rectangularly shaped electrical contact element 200.

In addition, the electrical contact element 200 comprises two welding sections 203-1, 203-2 that are provided on opposing sides at the edges of the electrical contact element 200 next to the mesh structures 201-1, 201-2.

With the welding sections 203-1, 203-2, the electrical contact element 200 may be wound around e.g., an inner conductor of a RF port, such that the welding sections 203-1, 203-2 overlap each other on the outside of the inner conductor. The welding sections 203-1, 203-2 may then be spot welded or laser welded together. In embodiments, the welding sections 203-1, 203-2 may also be welded to the inner conductor.

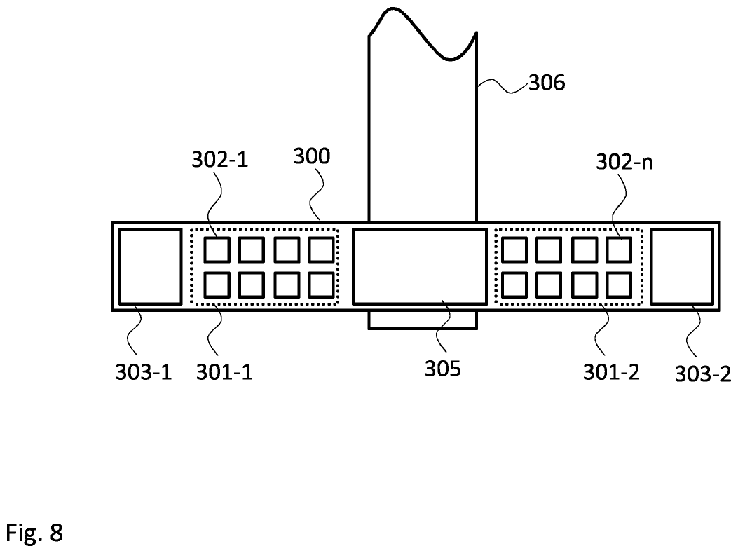

FIG. 8 shows a block diagram of another electrical contact element 300. The electrical contact element 300 is based on the electrical contact element 100. Therefore, the electrical contact element 300 comprises two mesh structures 301-1, 301-2. The mesh structures 301-1, 301-2 each comprise two rows each with four holes 302-1-302-n. The mesh structures 301-1, 301-2 are provided left and right of the center of the electrical contact element 300. The explanations provided regarding the electrical contact element 100, and the electrical contact element 200 apply mutatis mutandis to the electrical contact element 300.

As optional elements, the electrical contact element 300 comprises the two welding sections 303-1, 303-2 that are provided on opposing sides at the edges of the electrical contact element 300 next to the mesh structures 301-1, 301-2.

In addition, the electrical contact element 300 comprises a fixation section 305 that is provided between the mesh structures 301-1, 301-2. The fixation section 305 is, as well as the welding sections 303-1, 303-2, a section without holes. The fixation section 305 serves to fix the electrical contact element 300 e.g., to a trace 306, which is exemplarily shown in FIG. 8 under the electrical contact element 300.

The fixation section 305 may be spot welded or laser welded to the trace 306. Other fixation options, like gluing are also possible.

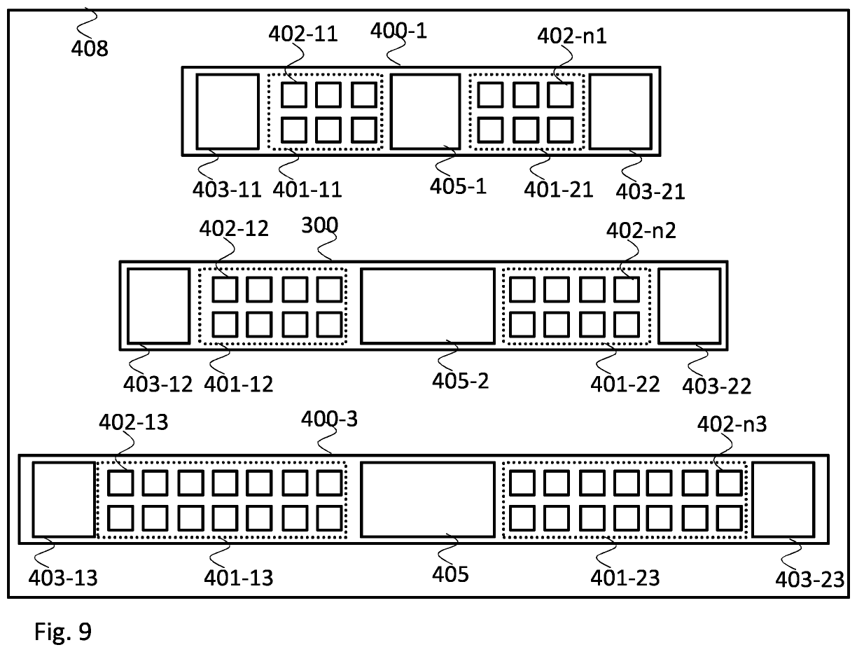

FIG. 9 shows a block diagram with multiple electrical contact elements 400-1, 400-2, 400-3, 400-4 that are provided on the same carrier substrate 408. Each one of the electrical contact elements 400-1, 400-2, 400-3, 400-4 is based on the electrical contact element 300. Therefore, the electrical contact elements 400-1, 400-2, 400-3, 400-4 each comprise two mesh structures 401-11, 401-21. 401-12. 401-22, 401-13, 401-23. The mesh structures 401-11, 401-21, 401-12, 401-22, 401-13, 401-23 are provided left and right of the centers of the electrical contact elements 400-1, 400-2, 400-3, 400-4. The explanations provided regarding the electrical contact element 100, the electrical contact element 200, and the electrical contact element 300 apply mutatis mutandis to the electrical contact elements 400-1, 400-2, 400-3, 400-4.

The electrical contact elements 400-1. 400-2, 400-3, 400-4 each comprises the two welding sections 403-11, 403-21, 403-21, 403-22, 403-13, 403-23 that are provided on opposing sides at the edges of the respective one of the electrical contact elements 400-1, 400-2, 400-3, 400-4 next to the respective mesh structures 401-11, 401-21. 401-12, 401-22, 401-13, 401-23.

Further, the electrical contact elements 400-1, 400-2, 400-3, 400-4 each comprise a fixation section 405-1, 405-2, 405-3, 405-4 that is provided between the mesh structures 401-11, 401-21, 401-12, 401-22, 401-13, 401-23. The fixation section 405-1, 405-2, 405-3, 405-4 is, as well as the welding sections 403-11, 403-21, 403-21, 403-22, 403-13, 403-23, a section without holes. The fixation section 405-1, 405-2, 405-3, 405-4 serves to fix the respective one of the electrical contact elements 400-1, 400-2, 400-3, 400-4 to a respective trace as shown for electrical contact element 300.

The mesh structures 401-11, 401-21 each comprise two rows each with three holes 402-11-402-n1. The mesh structures 401-12, 401-22 each comprise two rows each with four holes 402-12-402-n2. The mesh structures 401-13, 401-23 each comprise two rows each with seven holes 402-13-402-n3.

FIG. 9 serves to illustrate how multiple differently shaped electrical contact elements 400-1, 400-2, 400-3, 400-4 may easily be created on a single carrier substrate 408 with the method according to the present disclosure.

FIG. 10 shows another electrical contact element formed on a layered structure over a carrier substrate 508. The carrier substrate 508 carries a circuit structure 510. Over the circuit structure 510, and the carrier substrate 508, a separation layer 511 is provided. The separation layer 511 has a hole over a section of the circuit structure 510 that allows electrically contacting the circuit structure 510 through the hole. On the separation layer 511, and in the hole on the circuit structure 510, a seed layer 512 is provided, e.g., a gold layer. On top of the seed layer 512 a structuring layer 513 is provided. The structuring layer 513 comprises a hole where the separation layer 511 comprises the hole. However, the structuring layer 513 comprises further sections that do not comprise structuring layer material. These sections are just exemplarily provided directly adjacent to the left and right of the hole. In the hole and the further sections, the electrical contact element layer 514 is provided. The electrical contact element layer 514 reaches down to the section of the seed layer 512 that is not covered i.e., the hole in the separation layer 511, and fills the hole and the further sections of the structuring layer 513. Of course, multiple holes and other types of structures are also possible.

The arrangement of FIG. 10 shows the full stack of different layers that may be provided to form the electrical contact element, which essentially consists of the electrical contact element layer 514 being attached to the section of the seed layer 512 that is in the hole, which in turn is attached to the circuit structure 510.

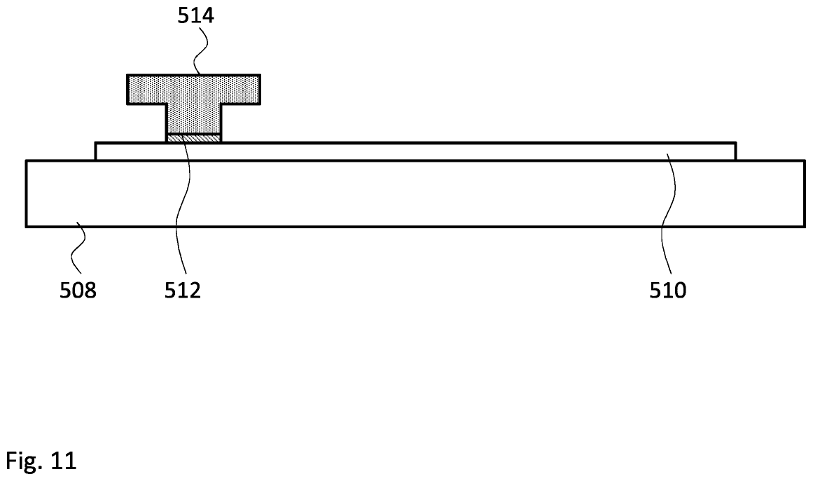

FIG. 11 shows another view of the arrangement of FIG. 10, wherein the non-required layers are removed after creating the electrical contact element.

The carrier substrate 608 carries a circuit structure 610. In a section of the circuit structure 610 that is not covered by the separation layer in FIG. 10, the seed layer 612 is present. Over that section of the seed layer 612, the electrical contact element layer 614 is arranged in the form of T, as already shown in FIG. 10.

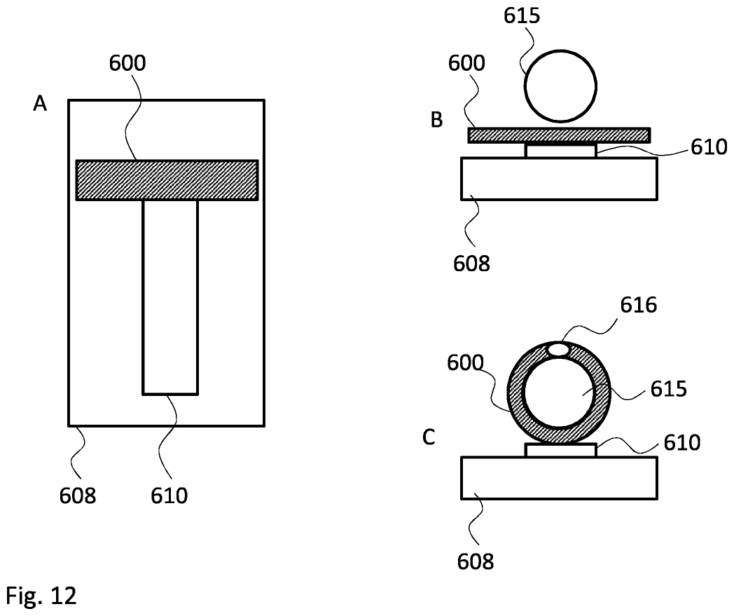

FIG. 12 shows a block diagram of another electrical contact element 600 that is arranged on a circuit structure 610 on a carrier substrate 608.

The circuit structure 610 is just exemplarily shown as straight trace or conductor. In other embodiments, any type of circuit structure 610 may be provided.

In FIG. 12, a first view, denoted as “A”, shows the carrier substrate 608 with the circuit structure 610, and the electrical contact element 600 in a top view. It can be seen, that the electrical contact element 600 is stripe-like shaped.

Another view, denoted as “B” shows a side view of the arrangement, in which the carrier substrate 608 is the lowest part with the circuit structure 610 between the carrier substrate 608, and the electrical contact element 600. Above the electrical contact element 600, a conductor 615 e.g., an inner conductor of a cable or port, is shown.

In a third view, denoted as “C”, the electrical contact element 600 is attached to the conductor 615. To this end, the conductor 615 is placed centered on the electrical contact element 600, and the stripe-like electrical contact element 600 is wound around the conductor 615. Schematically, a welding spot 616 is shown on the top side of the conductor 615, to fix the electrical contact element 600 to the conductor 615.

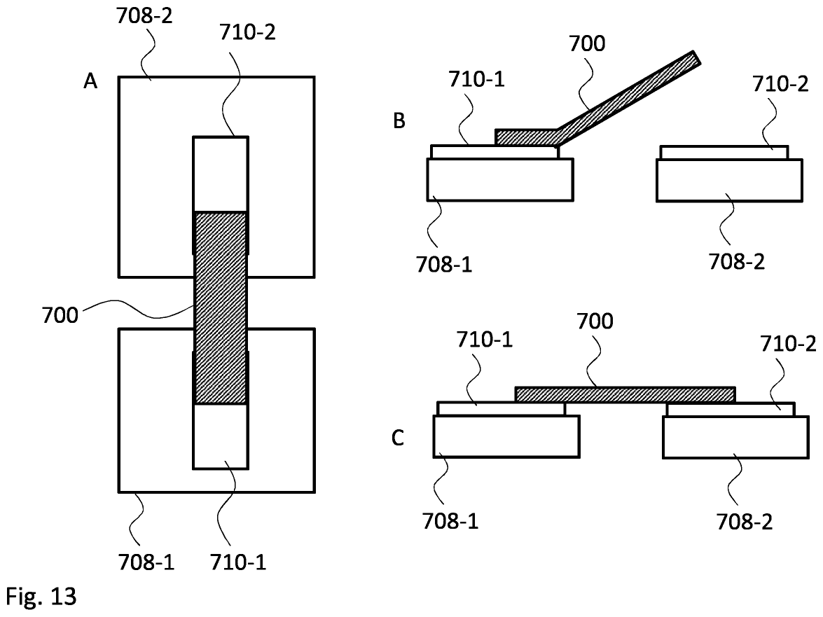

FIG. 13 shows a block diagram of another electrical contact element 700 that is arranged on a circuit structure 710-1 on a carrier substrate 708-1.

The circuit structure 710 is just exemplarily shown as straight trace or conductor. In other embodiments, any type of circuit structure may be provided, as already explained for FIG. 12.

In contrast to FIG. 12, in FIG. 13 a further carrier substrate 708-2 with another circuit structure 710-2 is shown, and the electrical contact element 700 serves for contacting the two circuit structures 710-1, 710-2.

In FIG. 13, a first view, denoted as “A”, shows the carrier substrates 708-1, 708-2 with the circuit structures 710-1, 710-2, and the electrical contact element 700 in a top view. It can be seen, that the electrical contact element 700 is stripe-like shaped between the two carrier substrates 708-1, 708-2.

Another view, denoted as “B” shows a side view of the arrangement, in which carrier substrates 708-1, 708-2 are shown carrying the circuit structures 710-1, 710-2. The electrical contact element 700 is shown being attached only to the circuit structure 710-1, and extending towards the second circuit structure 710-2 bent upwards. The electrical contact element 700 may be manufactured with a geometry as shown in order to interconnect two different circuit structures 710-1, 710-2. In other embodiments, both circuit structures 710-1, 710-2 may be provided on a single carrier substrate, and multiple electrical contact elements may be provided for a single circuit structure, or multiple circuit structures 710-1, 710-2 on a common carrier substrate.

In a third view, denoted as “C”, the electrical contact element 700 is attached to both circuit structures 710-1, 710-2.

In an embodiment, in a circuit structure multiple electrical contact elements as shown in FIG. 13, view “B”, may be formed without finally attaching the second end of the electrical contact elements. Such an arrangement may be formed to provide a kind of configurable circuit structure, wherein in the final application some of the electrical contact elements may be closed, while others may be removed.

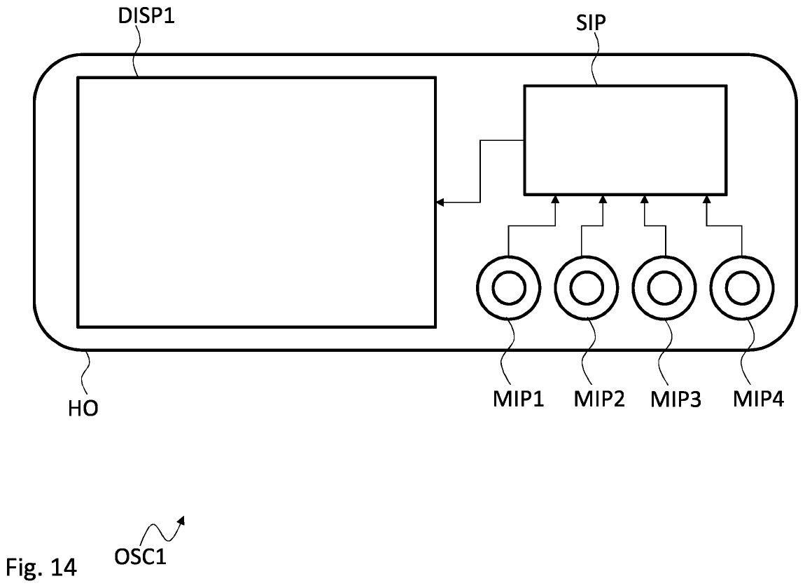

FIG. 14 shows a block diagram of an oscilloscope OSC1 that may be used with an embodiment of an electrical contact element according to the present disclosure. Embodiments of the electrical contact element may also be used with other devices, like spectrum analyzers, signal generators, network analyzers, emv testers, generally rf receiver/transceivers, especially regarding high frequencies up to 130 GHz cable-based.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

Although not explicitly shown, it is understood, that the oscilloscope OSC1 may also comprise signal outputs that may also be coupled to the differential measurement probe. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSC1 the measurement inputs MIP1, MIP2, MIP3, MIP4 may be measurement inputs for measuring electrical RF signals with frequencies in the microwave range. The measurement inputs MIP1, MIP2, MIP3, MIP4 may each comprise a port that comprises an inner conductor. These conductors may on the inside of the oscilloscope OSC1 be attached to respective traces or conductors of RF circuitry via electrical contact elements according to the present disclosure.

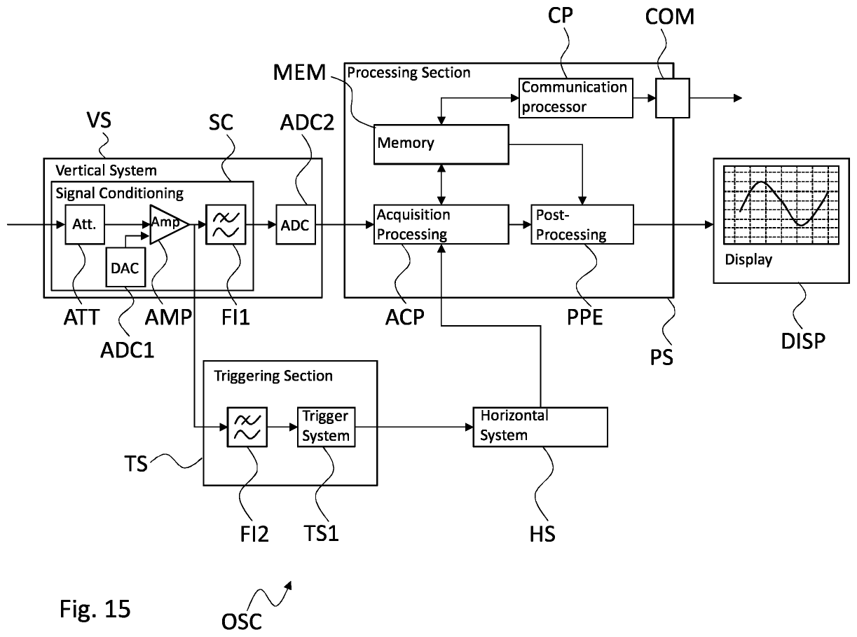

FIG. 15 shows a block diagram of an oscilloscope OSC that may be an implementation of a measurement application device that may be used with an electrical contact element according to the present disclosure. The oscilloscope OSC is implemented as a digital oscilloscope. However, the present disclosure may also be implemented with any other type of oscilloscope.

The oscilloscope OSC exemplarily comprises five general sections, the vertical system VS, the triggering section TS, the horizontal system HS, the processing section PS, and the display DISP. It is understood, that the partitioning into five general sections is a logical partitioning and does not limit the placement and implementation of any of the elements of the oscilloscope OSC in any way.

The vertical system VS mainly serves for offsetting, attenuating, and amplifying a signal to be acquired. The signal may for example be modified to fit in the available space on the display DISP or to comprise a vertical size as configured by a user.

In order to acquire RF signals, especially with frequencies in the range of microwaves, the oscilloscope OSC may comprise measurement inputs, that are coupled to the vertical system. The measurement inputs may each comprise a port that comprises an inner conductor. These conductors may on the inside of the oscilloscope OSC be attached to respective traces or conductors of RF circuitry via electrical contact elements according to the present disclosure. The RF circuitry may form part of the vertical system VS of the oscilloscope OSC.

To this end, the vertical system VS comprises a signal conditioning section SC with an attenuator ATT and a digital-to-analog-converter DAC that are coupled to an amplifier AMP1. The amplifier AMP1 is coupled to a filter FI1, which in the shown example is provided as a low pass filter. The vertical system VS also comprises an analog-to-digital converter ADC1 that receives the output from the filter FI1 and converts the received analog signal into a digital signal.

The attenuator ATT and the amplifier AMP1 serve to scale the amplitude of the signal to be acquired to match the operation range of the analog-to-digital converter ADC1. The digital-to-analog-converter DAC1 serves to modify the DC component of the input signal to be acquired to match the operation range of the analog-to-digital converter ADC1. The filter FI1 serves to filter out unwanted high frequency components of the signal to be acquired.

The triggering section TS operates on the signal as provided by the amplifier AMP. The triggering section TS comprises a filter FI2, which in this embodiment is implemented as a low pass filter. The filter FI2 is coupled to a trigger system TS1.

The triggering section TS serves to capture predefined signal events and allows the horizontal system HS to e.g., display a stable view of a repeating waveform, or to simply display waveform sections that comprise the respective signal event. It is understood, that the predefined signal event may be configured by a user via a user input of the oscilloscope OSC.

Possible predefined signal events may for example include, but are not limited to, when the signal crosses a predefined trigger threshold in a predefined direction i.e., with a rising or falling slope. Such a trigger condition is also called an edge trigger. Another trigger condition is called “glitch triggering” and triggers, when a pulse occurs in the signal to be acquired that has a width that is greater than or less than a predefined amount of time.

In order to allow an exact matching of the trigger event and the waveform that is shown on the display DISP, a common time base may be provided for the analog-to-digital converter ADC1 and the trigger system TS1.

It is understood, that although not explicitly shown, the trigger system TS1 may comprise at least one of configurable voltage comparators for setting the trigger threshold voltage, fixed voltage sources for setting the required slope, respective logic gates like e.g., a XOR gate, and FlipFlops to generate the triggering signal.

The triggering section TS is exemplarily provided as an analog trigger section. It is understood, that the oscilloscope OSC may also be provided with a digital triggering section. Such a digital triggering section will not operate on the analog signal as provided by the amplifier AMP but will operate on the digital signal as provided by the analog-to-digital converter ADC1.

A digital triggering section may comprise a processing element, like a processor, a DSP, a CPLD, an ASIC or an FPGA to implement digital algorithms that detect a valid trigger event.

The horizontal system HS is coupled to the output of the trigger system TS1 and mainly serves to position and scale the signal to be acquired horizontally on the display DISP.

The oscilloscope OSC further comprises a processing section PS that implements digital signal processing and data storage for the oscilloscope OSC. The processing section PS comprises an acquisition processing element ACP that is couple to the output of the analog-to-digital converter ADC1 and the output of the horizontal system HS as well as to a memory MEM and a post processing element PPE.

The acquisition processing element ACP manages the acquisition of digital data from the analog-to-digital converter ADC1 and the storage of the data in the memory MEM. The acquisition processing element ACP may for example comprise a processing element with a digital interface to the analog-to-digital converter ADC2 and a digital interface to the memory MEM. The processing element may for example comprise a microcontroller, a DSP, a CPLD, an ASIC or an FPGA with respective interfaces. In a microcontroller or DSP, the functionality of the acquisition processing element ACP may be implemented as computer readable instructions that are executed by a CPU. In a CPLD or FPGA the functionality of the acquisition processing element ACP may be configured in to the CPLD or FPGA opposed to software being executed by a processor.

The processing section PS further comprises a communication processor CP and a communication interface COM.

The communication processor CP may be a device that manages data transfer to and from the oscilloscope OSC. The communication interface COM for any adequate communication standard like for example, Ethernet, WIFI, Bluetooth, NFC, an infra-red communication standard, and a visible-light communication standard.

The communication processor CP is coupled to the memory MEM and may use the memory MEM to store and retrieve data.

Of course, the communication processor CP may also be coupled to any other element of the oscilloscope OSC to retrieve device data or to provide device data that is received from the management server.

The post processing element PPE may be controlled by the acquisition processing element ACP and may access the memory MEM to retrieve data that is to be displayed on the display DISP. The post processing element PPE may condition the data stored in the memory MEM such that the display DISP may show the data e.g., as waveform to a user. The post processing element PPE may also realize analysis functions like cursors, waveform measurements, histograms, or math functions.

The display DISP controls all aspects of signal representation to a user, although not explicitly shown, may comprise any component that is required to receive data to be displayed and control a display device to display the data as required.

It is understood, that even if it is not shown, the oscilloscope OSC may also comprise a user interface for a user to interact with the oscilloscope OSC. Such a user interface may comprise dedicated input elements like for example knobs and switches. At least in part the user interface may also be provided as a touch sensitive display device.

It is understood, that all elements of the oscilloscope OSC that perform digital data processing may be provided as dedicated elements. As alternative, at least some of the above-described functions may be implemented in a single hardware element, like for example a microcontroller, DSP, CPLD or FPGA. Generally, the above-describe logical functions may be implemented in any adequate hardware element of the oscilloscope OSC and not necessarily need to be partitioned into the different sections explained above.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software, and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, case of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

S1-S6, S1-1-S1-4, S2-1-S2-4 method steps
100, 200, 300, 600, 700 electrical contact element
400-1, 400-2, 400-3 electrical contact element
101-1, 101-2, 201-1, 201-2, 301-1, 301-2 mesh structure
401-11, 401-21, 401-12, 401-22 mesh structure
401-13, 401-23 mesh structure
102-1-102-n, 202-1-202-n mesh hole
302-1-302-n mesh hole
402-11-402-n1, 402-12-402-n2 mesh hole
402-13-402-n3 mesh hole
203-1, 203-2, 303-1, 303-2 welding section
403-11, 403-21, 403-12, 403-22 welding section
403-13, 403-23 welding section
305 fixation section
306 trace
408, 508, 608, 708-1, 708-2 carrier substrate
510, 610, 710-1, 710-2 circuit structure
511 separation layer
512 seed layer
513 structuring layer
514 electrical contact element layer
615 conductor
616 welding spot
OSC1 oscilloscope
HO housing
MIP1, MIP2, MIP3, MIP4 measurement input
SIP signal processing
DISP1 display
OSC oscilloscope
VS vertical system
SC signal conditioning
ATT attenuator
DAC1 analog-to-digital converter
AMP1 amplifier
FI1 filter
ADC1 analog-to-digital converter
TS triggering section
AMP2 amplifier
FI2 filter
TS1 trigger system
HS horizontal system
PS processing section
ACP acquisition processing element
MEM memory
PPE post processing element
DISP display

What is claimed is:

1. A method for manufacturing an electrical contact element on a circuit structure, the method comprising:
depositing a separation layer on a carrier substrate, wherein the carrier substrate comprises the circuit structure;
forming a structuring layer with a predefined structure on a basic layer that is arranged between the separation layer and the structuring layer;
adding an electrical contact element layer by depositing electrically conductive material on the basic layer via the structuring layer according to the predefined structure; and
removing the separation layer, and the structuring layer.

2. The method according to claim 1, wherein the separation layer is provided over at least part of the circuit structure and comprises at least one opening over at least a section of the circuit structure.

3. The method according to claim 1, wherein forming the separation layer comprises:
depositing a first photoresist layer on the basic layer;
exposing the first photoresist layer to a light source; and
developing the first photoresist layer.

4. The method according to claim 3, wherein forming the separation layer further comprises:
hardening the separation layer.

5. The method according to claim 1, wherein the separation layer comprises a thickness between 2 μm, and 50 μm.

6. The method according to claim 1, wherein the basic layer comprises a seed layer provided on the separation layer.

7. The method according to claim 6, wherein the seed layer is provided by at least one of DC magnetron sputtering, and a thermal evaporation process.

8. The method according to claim 6, wherein the seed layer is formed with a thickness between 5 nm and 300 nm.

9. The method according to claim 6, wherein the seed layer is formed of the same material as the electrical contact element layer.

10. The method according to claim 6, wherein the seed layer is removed at least in part with the separation layer, and the structuring layer.

11. The method according to claim 1, wherein forming the structuring layer comprises:
depositing a second photoresist layer on the basic layer;
exposing specific regions of the second photoresist layer to a light source, the specific regions being defined by the predefined structure; and
developing the second photoresist layer.

12. The method according to claim 11, further comprising:
hardening the structuring layer.

13. The method according to claim 1, wherein depositing electrically conductive material on the basic layer comprises at least one of DC magnetron sputtering, and a thermal evaporation.

14. The method according to claim 1, wherein the predefined structure comprises a mesh structure in at least a section of the structuring layer.

15. The method according to claim 14, wherein the distance between two holes in the mesh structure is between 5 μm and 15 μm; and
wherein the size of the holes in the mesh structure is smaller than 40 μm.

16. The method according to claim 1, wherein the predefined structure comprises at least one welding section, wherein the at least one welding section is provided on at least one of two opposing outer edges of the electrical contact element.

17. The method according to claim 1, wherein the predefined structure comprises at least one fixation section, wherein a mesh structure is provided on at least one of two opposing sides of the fixation section.

18. The method according to claim 1, further comprising repeating the steps of forming a structuring layer, and adding an electrical contact element layer for creating a 2.5-dimensional electrical contact element.

19. The method according to claim 1, further comprising repeating the steps of forming a structuring layer, and adding an electrical contact element layer for creating a bimetallic electrical contact element.

20. A Measurement application device comprising:
an electrical contact element manufactured by:
depositing a separation layer on a carrier substrate, wherein the carrier substrate comprises the circuit structure;
forming a structuring layer with a predefined structure on a basic layer that is arranged between the separation layer and the structuring layer;
adding an electrical contact element layer by depositing electrically conductive material on the basic layer via the structuring layer according to the predefined structure; and
removing the separation layer, and the structuring layer;
wherein the electrical contact element comprises:
at least one mesh structure.

21. The measurement application device according to claim 20, wherein the electrical contact element further comprises at least one welding section, wherein the at least one welding section is provided on at least one of two opposing outer edges of the electrical contact element, and the at least one mesh structure is provided between adjacent to the at least one welding section.

22. The measurement application device according to claim 20, wherein the electrical contact element further comprises at least one fixation section, wherein a mesh structure is provided on at least one of two opposing sides of the fixation section.

23. The measurement application device according to claim 20, wherein the electrical contact element further comprises at least one of a 2.5-dimensional structure, and a bimetallic structure.
